(19) United States
(12) Patent Application Publication
(10) Pub. No.: US 2004/0225951 A1
(43) Pub. Date: Nov. 11, 2004

(54) Bit error rate test system for multi-source agreement compliant transceivers

(76) Inventors: Dana L. Rose, San Jose, CA (US); Tom B. Mader, San Jose, CA (US); Robert J. DeBoo, San Jose, CA (US)

Correspondence Address: GROSSMAN & FLIGHT, LLC, 20 N. WACKER DRIVE, SUITE 4220, CHICAGO, IL, 60606, US

(21) Appl. No.: 10/027,053

(22) Filed: Dec. 20, 2001

(51) Int. Cl. H03M 13/00

(52) U.S. Cl. 714/819

(57) ABSTRACT

A bit error rate test system for testing multi-source agreement (MSA) compliant transceivers is disclosed. The bit error rate test system is fabricated on a printed circuit board that includes an integral MSA compliant connector. An MSA compatible transceiver may be directly connected to the test system via the MSA compliant connecter, thereby eliminating the need for interposing cables, wires and/or additional interface boards.

### FIELD OF THE INVENTION

The present invention relates generally to bit error rate test equipment and, more particularly, to a bit error rate test system for use with multi-source agreement compliant transceivers.

### DESCRIPTION OF THE RELATED ART

Known bit error rate (BER) test systems are typically general purpose in nature and, thus, provide a high level of application flexibility, programmability, etc. In particular, to provide a high level of interface flexibility, known BER test systems typically provide a large number of input/output (I/O) ports or signal lines, each of which may be implemented using a separate flexible cable, wire, etc. For example, many known BER test systems provide a large number of cables or wires for interfacing with products to be tested.

While the flexible nature of known BER test systems permits their use in testing a wide range of product types, configurations, etc., these known BER test systems are relatively complex, physically bulky, and expensive. Furthermore, because known BER test systems typically provide a large number of interface cables or wires, it is usually necessary to develop a complex interface circuit board to adapt and/or route these cables or wires (or the signals carried thereby) to the device or product being tested. In some cases, each BER test system may provide several dozen interface cables or wires which, as a practical matter, preclude use of these BER test systems in large numbers, in a temperature controlled oven, etc.

When testing digital communications equipment having an inherently low BER, it is necessary to test the equipment for a long period of time such as, for example, two thousand hours, to achieve statistically reliable test results for each piece of equipment or device under test (DUT). Additionally, it may be necessary to characterize or test digital communications equipment at various temperatures and/or under other varying environmental conditions to determine whether the BER for the communications equipment is within published specifications, desired manufacturing tolerances, etc. Unfortunately, the relatively high costs of known BER test systems may limit the number of BER test systems that can be purchased and, as a result, if a long test time is needed, production throughput may be limited by the number of BER test systems that a manufacturer can afford to purchase and maintain. Furthermore, the relatively large size of known BER test systems may also limit the number of BER test systems that may be placed within the space constraints of a factory test area and may make it impractical to perform BER testing on products under varying environmental conditions within environmental test chambers and the like.

### BRIEF DESCRIPTION OF THE DRAWINGS

FIG. 1 is an exemplary functional block diagram of a system that may be used to detect bit errors and determine the bit error rate of a multi-source agreement compliant device;

FIG. 2 is an exemplary flow diagram that depicts one manner in which the system shown in FIG. 1 may be used to test bit errors within a multi-source agreement compliant device;

FIG. 3 is an exemplary block diagram of a printed circuit assembly implementation of the system shown in FIG. 1; and

FIG. 4 is a detailed schematic block diagram that illustrates one manner in which the systems shown in FIGS. 1 and 3 may be implemented.

### DESCRIPTION

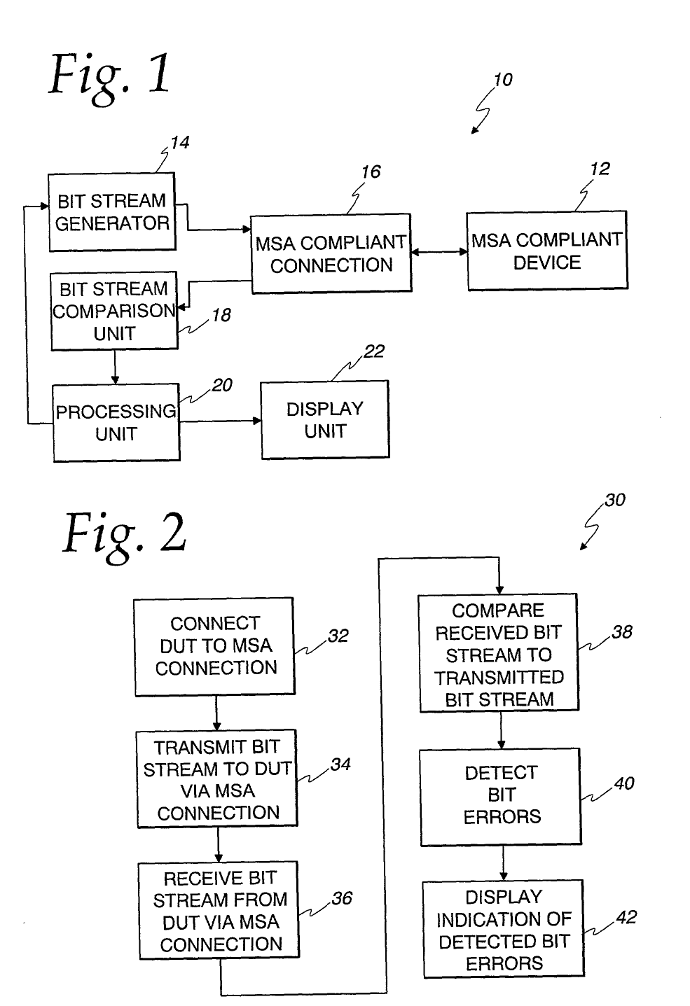

FIG. 1 is an exemplary functional block diagram of a system 10 that may be used to detect bit errors and determine the bit error rate of a multi-source agreement (MSA) compliant device 12. As shown in FIG. 1, the system 10 includes a bit stream generator 14, which is adapted to generate a bit stream to be transmitted to the MSA compliant device 12. The MSA compliant device 12 may be an optical transceiver such as, for example, the SERDES (i.e., serializer/deserializer) fiber optic transceiver commercially available from Intel Corporation that has been configured in a loop-back mode to permit BER testing of the device 12. Of course, any other MSA compliant device may be used for the device 12 within the system 10 of FIG. 1. Preferably, the bit stream generator 14 is adapted to generate a bit stream having a pseudo-random sequence of bit values (i.e., logical ones and logical zeros). The bit stream generated by the bit stream generator 14 is coupled or otherwise conveyed or communicated to the MSA compliant device 12 via the an MSA compliant connection 16. Preferably, the bit stream generator 14 is directly electrically coupled to the MSA compliant connection 16 so that additional interposing mechanical and/or electrical components such as cables, wires, etc. are not needed. The MSA compliant connection 16 is preferably configured according to the 300 pin 10 gigabit MSA electrical connector specifications, which have been widely published since Apr. 16, 2001. In general, the MSA compliant connection 16 is implemented using a connector having a unitary body including a plurality of electrical contacts. For example, the connector used to implement the MSA compliant connection 16 may be a 300 pin grid array type connector, which are commercially available from at least Berg Inc. and Framatone Connectors International (see, for example, Framatone Connectors International part number 84500-002). The connector used to implement the MSA compliant connection 16 may be mounted to a printed circuit board or any other suitable circuit substrate. The 300 pin 10 gigabit MSA specifications are well known and, thus, the detailed mechanical and electrical requirements associated with implementing the MSA compliant connection 16 are not described in greater detail herein. See, for example, the web page at: http://www.alcatel.com/telecom/optronics/products/6ois/pdf/msa64trx.pdf.

The MSA compliant connection 16 is preferably configured to enable the MSA compliant device 12 to be directly coupled, mechanically and electrically, to the connection 16. Thus, in contrast to known BER test systems, the system 10 enables an MSA device under test such as, for example, the MSA compliant device 12, to be connected for BER testing without requiring a plurality of cables, wires, etc. and without requiring an additional interposing signal routing/interface circuit board.

The system 10 also includes a bit stream comparison unit 18 that is directly electrically coupled to the MSA compliant connection 16 and which receives a bit stream from the MSA compliant device 12 via the MSA compliant connection 16. In the case where the system 10 is used to detect a bit error and/or to determine a bit error rate associated with the MSA compliant device 12 (which may, for example, be an optical transceiver connected in a loop back configuration), the bit stream comparison unit 18 compares the received bit stream to the bit stream originally sent by the bit stream generator 14 to the MSA compliant device 12 via the MSA compliant connection 16. Each difference between the sequence of bit values sent by the bit stream generator 14 and the sequence of bit values received from the MSA compliant device 12 by the bit stream comparison unit 18, is stored, accumulated or otherwise accounted for within the bit stream comparison unit 18.

The system 10 further includes a processing unit 20 which may, for example, be implemented using a reduced instruction set computer, processor or microcontroller, or any other device suitable for processing program instructions. The processing unit 20 is coupled to the bit stream comparison unit 18 and the bit stream generator 14 and is adapted to determine a bit error rate of the MSA compliant device 12 based on the results of the comparison of the bit stream generated by the bit stream generator 14 and the bit stream received from the MSA compliant device 12. In particular, the results of the comparison performed by the bit stream comparison unit 18 may be an accumulation or total number of bit errors (i.e., bit value sequence differences or errors) detected over a given time interval. In that case, the BER equals the total number of bit errors divided by the total number of bit values provided within the bit stream during the given time interval. In the case where the bit stream signal has a constant frequency, which is typically the case, the total number of bit values contained within a given time interval equals the frequency of the bit stream signal multiplied by the duration of the time interval.

The system 10 may also include a display unit 22 that is in communication with the processing unit 20. The display unit 22 may be adapted to display a numeric value representative of a bit error rate of the MSA compliant device 12. Alternatively or additionally, the display unit 22 may provide a light source such as, for example, a light-emitting diode or any other suitable light source that is illuminated in response to detection of at least one bit error by the bit stream comparison unit 18. If desired, the bit stream comparison unit 18 may communicate directly with the display unit 22 to cause the display unit 22 to display a numeric value representative of a bit error rate and/or to illuminate a light source indicative of at least one bit error.

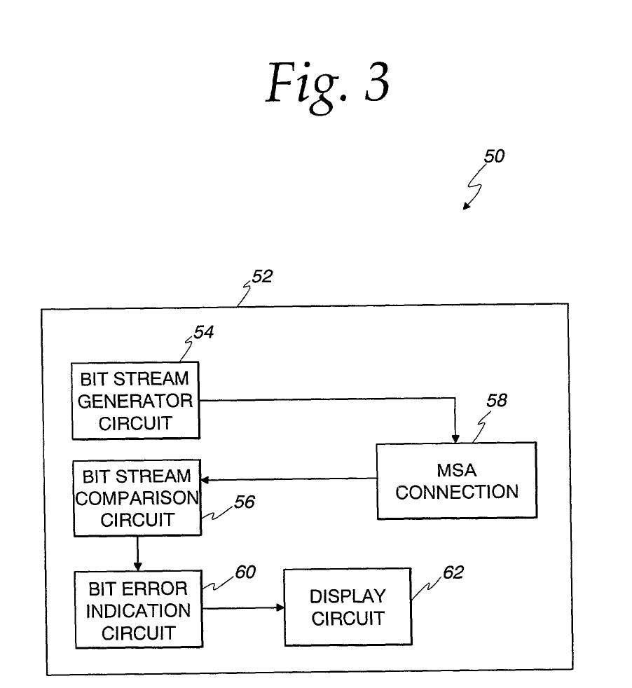

FIG. 2 is an exemplary flow diagram 30 that depicts one manner in which the system 10 shown in FIG. 1 may be used to test bit errors within a multi-source agreement compliant device. At block 32 the device under test (DUT), which in this example is the MSA compliant device 12, is connected to the MSA compliant connection 16. Preferably, the DUT is directly connected to the MSA compliant connection 16 and, thus, does not require any interposing cables, wires, circuit boards, etc. At block 34, the bit stream generator 14 transmits a bit stream to the DUT (i.e., the MSA compliant device 12). The transmitted bit stream has a sequence of bit values which may, for example, be a pseudo-random sequence, or any other desired sequence suitable for detecting bit errors and/or the bit error rate of the DUT. In the case where the DUT is an optical transceiver, for example, and is connected in a loop-back configuration, the transmitted bit stream is received by the DUT, conveyed through a length of fiber optic cable and is retransmitted by the DUT to the bit stream comparison unit 18 through the MSA compliant connection 16. However, line losses, interference, insufficient sensitivity at the DUT, etc. may cause the bit stream transmitted by the DUT to have one or more bit errors so that the received and transmitted bit streams may have different bit value sequences.

At block 36 the bit stream comparison unit 18 receives the bit stream transmitted by the DUT via the MSA compliant connection 16. At block 38 the bit stream comparison unit 18 compares the bit stream received from the DUT to the bit stream originally transmitted by the bit stream generator 14 and based on the comparison, at block 40, the bit stream comparison unit 18 and/or the processing unit 20 detects or determines if there are any bit errors. For example, the bit stream comparison unit 18 and/or the processing unit 20 may accumulate and sum the total number of bit errors for a given time period to enable a calculation of the bit error rate of the DUT. At block 42 the display unit 40 displays an indication of the bit errors detected at block 40. The display unit 22 may illuminate a light to indicate the occurrence of at least one bit error and/or may provide a numeric display of the bit error rate calculated at block 40.

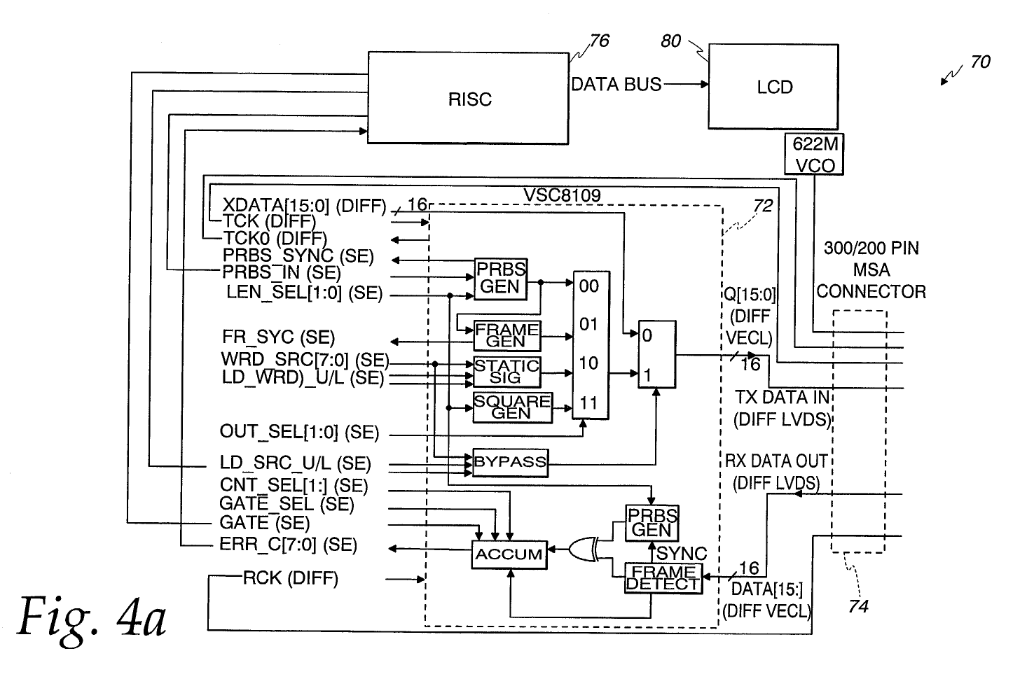

FIG. 3 is an exemplary block diagram of a printed circuit assembly 50 implementation of the system 10 shown in FIG. 1. The printed circuit assembly 50 includes a printed circuit board or substrate 52, which may be fabricated using any desired technique. A bit stream generator circuit 54, which performs the function of the bit stream generator 14 (FIG. 1), is disposed on the printed circuit board 52. Similarly, a bit stream comparison circuit 56, which performs the function of the bit stream comparison unit 18 (FIG. 1), is also disposed on the printed circuit board 52. Additionally, a multi-source agreement compliant connection or connector 58, which may be implemented using the 300 pin grid array type connector discussed above, is fixed to the printed circuit board 52, thereby enabling the MSA compliant device 12 (FIG. 1) to be directly mechanically and electrically coupled or connected to the printed circuit assembly 50.

Still further, a bit error indication circuit 60 is disposed on the printed circuit board 52. The bit error indication circuit 60 is further adapted to communicate with a display circuit 62 disposed on the printed circuit board 52. The bit error indication circuit 60 and the display circuit 62 function to display an indication of at least one bit error and/or a numeric bit error rate value associated with an MSA compliant device such as, for example, the device 12 shown in FIG. 1. By way of example only, the bit error indication circuit 60 may be a memory register, accumulator or any other circuit or device that enables one or more bit errors to be accumulated. The display circuit 62 may include a driver circuit and a light source (e.g., a light-emitting diode) that illuminates when the display circuit 62 receives a communication or signal from the bit error indication circuit 60 to indicate that one or more bit errors have been detected. Alternatively or additionally, the display circuit 62 may be a numeric display adapted to display a bit error rate value associated with the device being tested. For example, the display circuit 62 may use a liquid crystal display (LCD), a plasma display or any other display that enables numeric display of a bit error rate.

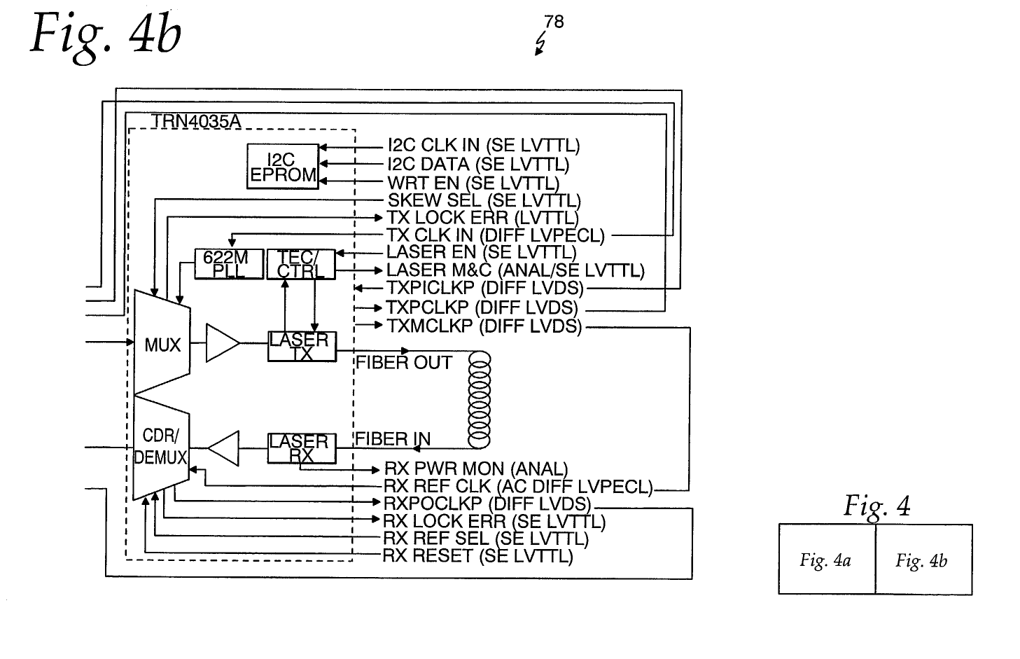

FIG. 4 is a detailed schematic block diagram 70 that illustrates one manner in which the systems 10 and 50 shown in FIGS. 1 and 3, respectively, may be implemented. As shown in FIG. 4, a pattern generation and detection integrated circuit 72 is directly coupled or connected to an MSA compliant connector 74. In the example shown, the pattern generation and detection integrated circuit 72 is a Vitesse 8109 chip. However, any other integrated circuit or chip that generates a bit stream and which compares a received bit stream to the transmitted bit stream may be used instead. A reduced instruction set computer (RISC), processor or microcontroller 76 is in communication with the pattern generation and detection integrated circuit 72. The RISC 76 acquires accumulated bit errors from the pattern generation and detection circuit 72 and processes the bit errors to calculate a bit error rate for an optical transceiver 78. The RISC 76 also communicates with a liquid crystal display 80, which may be used to numerically display the bit error rate of the optical transceiver 78. In the example shown in FIG. 4, the optical transceiver 78 is a SERDES fiber optic transceiver manufactured by Intel Corporation. However, any other MSA compliant transceiver could be used instead.

In contrast to known BER test systems and techniques, the implementation shown in FIG. 4 may be easily fabricated on a single printed circuit assembly such as, for example, the printed circuit assembly 50 shown in FIG. 3. In that case, the circuitry shown in FIG. 4 can be made inexpensively and relatively compact, which enables a large number of BER test systems to be used within one or more environmental test chambers, if desired. As a result, the BER test system and techniques described herein enable relatively high throughput BER testing of optical transceivers and the like at a relatively low cost.

Although certain apparatus constructed in accordance with the teachings of the invention have been described herein, the scope of coverage of this patent is not limited thereto. On the contrary, this patent covers all embodiments of the teachings of the invention fairly falling within the scope of the appended claims either literally or under the doctrine of equivalents.

What is claimed is:

1. A system for detecting bit errors within a received bit stream, the system comprising:
a bit stream comparison unit that is adapted to compare a first bit value sequence of the received bit stream to a second bit value sequence associated with a transmitted bit stream to detect a sequence difference between the first and second bit value sequences; and
a multi-source agreement compliant electrical connector, wherein the multi-source agreement compliant electrical connector is adapted to convey the transmitted and received bit streams and is in communication with the bit stream comparison unit, and wherein the multi-source agreement compliant electrical connector is adapted to be directly mechanically and electrically coupled to a multi-source agreement compliant device.

2. The system of claim 1, wherein the bit stream comparison unit and the multi-source agreement compliant electrical connector are integrated on a circuit substrate.

3. The system of claim 2, wherein the circuit substrate is a printed circuit board.

4. The system of claim 1, wherein the multi-source agreement compliant device is an optical transceiver.

5. A system for determining a bit error rate of a device under test, the system comprising:
a bit stream generator adapted to generate a first bit stream to be transmitted to the device under test;
a bit stream comparison unit adapted to compare a second bit stream received from the device under test to the first bit stream;
a processing unit coupled to the bit stream generator and the bit stream comparison unit adapted to determine the bit error rate of the device under test based on the comparison of the second bit stream to the first bit stream; and
an electrical connector including a unitary connector body, wherein the electrical connector is adapted to directly couple to a multi-source agreement compliant connection associated with the device under test.

6. The system of claim 5, further including a display unit coupled to the processing unit, wherein the display unit is adapted to display the bit error rate of the device under test.

7. The system of claim 5, wherein the device under test includes an optical transceiver.

8. The system of claim 5, wherein the processing unit includes a reduced instruction set computer.

9. The system of claim 5, further including a light source that illuminates in response to detection of at least one bit error associated with the second bit stream.

10. A printed circuit assembly for use in detecting a bit error rate, the printed circuit assembly comprising:
a printed circuit board;
a bit stream generation circuit disposed on the printed circuit board;
a bit stream comparison circuit disposed on the printed circuit board and adapted to generate an output for use in detecting the bit error rate; and
a multi-source agreement compliant electrical connector disposed on the printed circuit board and electrically coupled to the bit stream generation circuit and the bit stream comparison circuit.

11. The printed circuit assembly of claim 10, further including a display circuit adapted to provide an output indicative of one of a bit error and the bit error rate.

12. The printed circuit assembly of claim 11, wherein the output indicative of the one of the bit error and the bit error rate is one of a light source and a displayed numeric value.

13. An apparatus for testing a multi-source agreement compliant optical transceiver, comprising:
a printed circuit substrate;
a bit stream generation circuit disposed on the printed circuit substrate;
a bit stream comparison circuit disposed on the printed circuit substrate;
a multi-source agreement compliant electrical connector disposed on the printed circuit substrate and electrically coupled to the bit stream generation circuit and the bit stream comparison circuit; and
a bit error indication circuit disposed on the printed circuit substrate.

14. The apparatus of claim 13, wherein the bit error indication circuit is adapted to illuminate a light source disposed on the printed circuit substrate.

15. The apparatus of claim 13, wherein the bit error indication circuit is adapted to generate a signal that causes a numeric display device to display a bit error rate value associated with the multi-source agreement compliant optical transceiver.

16. A method of testing an optical transceiver, comprising:
directly connecting the optical transceiver to a printed circuit assembly via a multi-source agreement compliant connection;
transmitting a first bit stream from the printed circuit assembly to the optical transceiver via the multi-source agreement compliant connection;
receiving a second bit stream from the optical transceiver at the printed circuit assembly via the multi-source agreement compliant connection;
comparing the first and second bit streams at the printed circuit assembly;
detecting a bit error of the optical transceiver based on the comparison of the first and second bit streams; and
displaying an indication of the detected bit error via a display device.

17. The method of claim 16, further including calculating a bit error rate of the optical transceiver based on the comparison of the first and second bit streams.

18. The method of claim 17, further including displaying the bit error rate via the display device.

19. The method of claim 18, wherein directly connecting the optical transceiver to the printed circuit assembly via the multi-source agreement compliant connection includes attaching the optical transceiver to the printed circuit assembly via a unitary connector mounted to the printed circuit assembly.

20. A method of determining a bit error rate for each of a plurality of MSA compliant optical transceivers, the method comprising:
directly connecting each of the plurality of MSA compliant optical transceivers to a respective one of a plurality of printed circuit assemblies, each of which includes an MSA compliant connection and each of which is adapted to detect bit errors in a bit stream received from its respective one of the plurality of MSA compliant optical transceivers;
placing the plurality of MSA compliant optical transceivers and the plurality of printed circuit assemblies in an environmental test chamber; and
detecting bit errors associated with each of the plurality of MSA compliant optical transceivers while each of the plurality of MSA compliant optical transceivers is under test in the environmental test chamber.

21. The method of claim 20, further including calculating a bit error rate for each of the plurality of MSA compliant optical transceivers.

22. The method of claim 21, further including displaying an indication of one of the detected bit errors and bit error rates via a plurality of display devices, each of which is uniquely associated with one of the plurality of MSA compliant optical transceivers.
